(19) United States
(12) Patent Application Publication
(10) Pub. No.: US 2004/0086037 A1
(43) Pub. Date: May 6, 2004

(54) Noise reduction apparatus

(76) Inventor: Tadao Sugita, Tokyo (JP)

Correspondence Address: Oliff & Berridge, PO Box 19928, Alexandria, VA, 22320, US

(21) Appl. No.: 10/380,110

(22) PCT Filed: Jul. 30, 2002
(86) PCT No.: PCT/JP02/07755

(30) Foreign Application Priority Data
Jul. 30, 2001 (JP) 2001-229506

(51) Int. Cl. H03K 9/08; H03K 7/08

(52) U.S. Cl. 375/238

(57) ABSTRACT

Since the frequency band after the spread spectrum modulation is wide, the frequency of 2.4 GHz band of the ISM (Industrial Scientific Medical) band as a modulation carrier frequency, is specified, so that the current state, in which the spread spectrum communication system can not be applied to the transmission by the frequencies other than 2.4 GHz band, is considered, and thus the noise reduction effect equal with the spread spectrum communication system was obtained in the signal transmission in the frequencies other than 2.4 GHz band, thereby obtaining a construction, in which the spread spectrum modulation is performed only at receiving side.

Noise reduction apparatus according to the present invention comprises a differentiating circuit for converting pulse string (SS signal) into sawtooth pulse string signal, means for pulse-width-modulating the converted sawtooth pulse string signal with input signals, and means for outputting the sawtooth pulse string signals which are pulse-width modulated with the above input signal as an output signal, only at the time during which the pulse-width-modulated sawtooth pulse string signal is more than a given level.

### PRIOR ART

The present invention relates to a noise reduction apparatus that can be used for the whole of analog transmission and digital transmission, as well as its utilization apparatus, and a carrier regenerative device for reproducing the carrier used for it.

Spread spectrum (SS) communication method is known as a communication method to which the noise reduction effect is had. This system is a system for transmitting signals by expanding its frequency spectrum as shown in its name. As a general construction of the transmission system, the baseband signal is modulated by the spread signal and transmitted at the transmission side, and at receiving side, the received signal is again modulated (referred to as the reverse spread modulation) by the same spread signal as the transmission side, and the obtained signal is passed through a low-pass filter, thereby recovering baseband signals. As to the spread spectrum communication, refer to for example a publication written by Yamauchi “Spread spectrum communication” published by Tokyo Denki University Press, November, 1994.

The noise reduction effect (S/N improvement effect) according to the communication method is equal to a spread coefficient of the spread signal, so that if the spread coefficient is 100 times, a large S/N improvement effect of 40 dB is obtained. (Refer to on page 35 of a publication “Wireless data transmission technology by the electric wave”, published by CQ Publishing Co., Ltd.).

In this manner, the noise reduction effect of the spread spectrum communication system is large, but on adopting the system, the frequency band after the spread modulation is wide, so that it is specified to the frequency more than 2.4 GHz band of the ISM (Industrial Scientific and Medical ) band as a carrier frequency performing the modulation of the signal, therefore, the spread spectrum communication system cannot be applied to transmission by the frequency below 2.4 GHz band.

### DESCRIPTION OF THE INVENTION

An object of the present invention is to provide a noise reduction apparatus capable of obtaining the noise reduction effect equal to the spread spectrum communication system, even in the signal transmission of frequency band below the above 2.4 GHz band.

To achieve the above object, an apparatus for reducing noises by performing the spread spectrum modulation only at receiving side according to the present invention comprises means for converting a rectangular pulse string into a steep sawtooth pulse string, means for pulse width modulating input signals with a steep sawtooth pulse string from the pulse string conversion means, and means for outputting steep pulse string which is pulse width modulated by the pulse width modulation means, whereby the noise reduction is performed so as to improve the signal-to-noise ratio of the above output signal compared with the signal-to-noise ratio of the above input signal.

Moreover, noise reduction apparatus according to the present invention further comprises a pulse width extension circuit for extending the pulse width of the steep pulse string which is pulse width modulated, at following stage.

The above steep sawtooth pulse string conversion means is a differentiating circuit.

Moreover, a carrier regenerative device for generating pulse string synchronized with input signal to be supplied to the noise reduction apparatus according to the present invention comprises means for taking out carrier components by filtering and amplifying input signal, and means for performing slave oscillation by amplifying the carrier component taken out to perform positive feedback to input side of carrier component taking out means.

The carrier component extracting means is a first vibrator and the slave oscillation means is a second vibrator.

The above vibrator is a quartz vibrator or a ceramic vibrator.

### BRIEF DESCRIPTION OF THE DRAWING

FIG. 1 is a fundamental block diagram of an SS communication system.

FIG. 2 shows a waveform of spread signal at the transmission side, a waveform of received input signal at the receiving side, and a waveform of output signal of the SS modulator, respectively.

FIG. 3 is a fundamental block diagram of noise reduction apparatus according to the present invention.

FIG. 4 shows the strength of the signals derived when the sinusoidal wave is sampled by the SS signal that is not synchronized with the sinusoidal wave, assuming that SS signal, pulse string in the case of duty ratio D_{R} being 0.5(T_{C}=T_{B}/2) and, the baseband signal being a sinusoidal wave of analog signal.

FIG. 5 shows the relation of Nₒ/Nᵢ=2D_{R}, the relation of Sₒ/Sᵢ=2/π≅−3.9 dB, and the relation of Sₒ/Sᵢ=1.

FIG. 6 is one constructional embodiment of a convenient pulse width modulation circuit constituted by using the inverter element to realize an implementation of the present invention.

FIG. 7 shows signal waveforms of the parts shown in the circuit of FIG. 6 by signs a, b, and c, respectively.

FIG. 8 shows the situation in which the SS signal is subjected to pulse width modulation.

FIG. 9 shows the SS modulation circuit represented by schematic symbol.

FIG. 10 shows a constructional embodiment in which the SS modulator is cascaded by as many as three steps through the amplifier.

FIG. 11 is a pulse width modulation amplifier circuit to which the noise reduction apparatus according to the present invention is applied.

FIG. 12 shows the detailed circuit diagram thereof.

FIG. 13 is a waveform diagram of signals at the points (a) to (h) of respective portions in FIG. 12, which shows operation of the pulse width modulating and amplifying circuit.

FIG. 14 is a circuit diagram showing the construction of the noise reduction high-gain antenna portion of the medium wave radio band, to which the noise reduction apparatus according to the present invention is applied.

FIG. 15 is a detailed circuit diagram showing the tuning and amplifying circuit of FIG. 14.

FIG. 16 is a circuit diagram showing the construction of the noise reduction high-gain antenna portion of the medium wave radio band that applies the noise reduction apparatus according to the present invention.

FIG. 17 is a circuit diagram showing the construction of the noise, interference, and multipath disturbance reduction receiver that applies the noise reduction apparatus according to the present invention.

FIG. 18 is a waveform diagram explaining the operation that removes the interference and jamming wave component in the receiver of FIG. 17.

FIG. 19 is a waveform diagram explaining the operation that removes the multipath disturbance component.

FIG. 20 is a circuit diagram showing the construction of a carrier reproduction and a local oscillating section in the receiver shown in FIG. 17.

FIG. 21 is an explanatory view showing the relation among signal frequency fr, local frequency fl, and IF frequency fi.

FIG. 22 is a circuit diagram showing the construction of a multistep synchronous sampling portion in the receiver shown in FIG. 17.

FIG. 23 is a waveform diagram of signals at the points (i) to (n) of respective portions in FIG. 22, which shows an operation of multistep synchronous sampling section.

### BEST MODE FOR CARRYING-OUT OF THE INVENTION

The present invention is explained in detail based on the Detailed Description of the Preferred Embodiments referring to the attached drawing as follows.

First of all, before explaining the present invention, a well-known spread spectrum communication system (hereafter, referred to as an SS communication system) is explained.

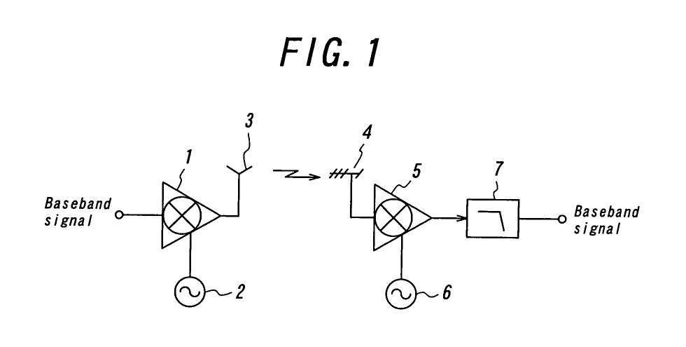

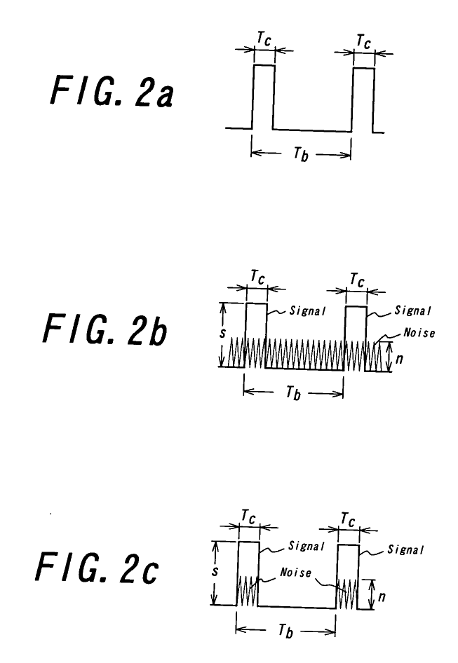

FIG. 1 is a fundamental constructive block diagram of the SS communication system. Moreover, FIGS. 2(a), 2(b) and 2(c) show waveform of spread signal at the transmission side, waveform of received input signal at the reception side, and waveform of output signal of SS modulator, respectively.

In the SS communication system, the baseband signal is supplied to an SS modulator 1 at the transmission side as shown in FIG. 1, and the spread signal of the waveform shown in FIG. 2a (hereafter, referred to as an SS signal) is also supplied to the SS modulator 1 from an spread signal source 2, thereby transmitting the baseband signal modulated by the SS signal, from a transmission antenna 3.

On the other hand, in receiving side, similarly as shown in the FIG. 1, the reception input signal (this is shown in FIG. 2b) received by a receiving antenna 4 is supplied to an SS modulator 5, quite the same signal (signal of the waveform shown in FIG. 2a) as the signal generated in the SS signal source 2 at the transmission side, is generated from an SS signal source 6 in synchronization with the transmission side, and the received input signal is SS modulated with the generated signal. Thus SS-modulated signal is shown in FIG. 2c. The SS-modulated signal is derived as a baseband signal through a low pass filter 7 for the harmonic signal elimination.

Here, the S/N improvement according to the SS communication system is examined.

Now, assuming that the SS signal shown in FIG. 2a is a pulse string having pulse width T_{c}, pulse duration T_{b}, and thus duty ratio T_{c}/T_{b} (hereafter, referred to as duty ratio D_{R}), signal strength of the reception input signal is Sᵢ, the noise strength of the reception input signal is Nᵢ, the signal strength of SS modulated (at receiving side) output signal is Sₒ, and, the noise strength of SS modulated (at receiving side) output signal is Nₒ, following relations can be obtained.

From Sᵢ=sT_{c}

Nᵢ=nT_{b},

Sᵢ/Nᵢ=sT_{c}/nT_{b} (1)

From Sₒ=sT_{c}

Nₒ=nT_{c},

Sₒ/Nₒ=s/n (2)

where, n and s are levels of noise and signal shown in FIG. 2b and FIG. 2c, respectively.

From the above, S/N improvement effect ((S/N)up) according to the SS communication system is shown as follows by taking the ratio of the equation (2) and the equation (1),

$$\begin{matrix}( S / N ) up = ( {S}_{o} / {N}_{o} ) \cdot ( {N}_{i} / {S}_{i} ) \\ = {T}_{b} / {T}_{c} = 1 / {D}_{R}\end{matrix} \qquad ( 3 )$$

Moreover, in the field of the SS communication, T_{b} is a bit section, T_{c} is a chip section, and its ratio T_{b}/T_{c} is referred to as a spread coefficient or a processing gain, thereby representing an S/N improvement effect.

The above is a conventional SS communication system, in which the same SS signal is used at the transmission side and at the receiving side, and the same SS modulation is performed. This will repeat the same signal processing (SS modulation) twice in one transmission system, so that even if the SS modulation at the transmission side is omitted and the SS modulation is performed only at receiving side, the S/N improvement effect is sure to be obtained.

The noise reduction method according to the present invention is obtained under such an idea.

Hereinafter, the noise reduction apparatus according to the present invention is explained.

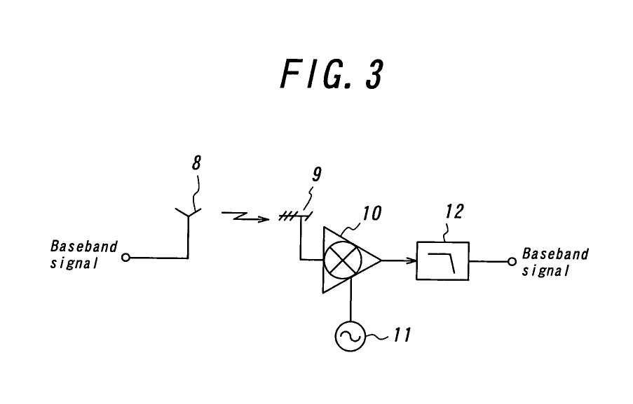

FIG. 3 is a fundamental block diagram of a noise reduction apparatus according to the present invention.

In FIG. 3, 8 is a transmission antenna, 9 is a receiving antenna, 10 is an SS modulator, 11 is an SS signal source and 12 is a low pass filter. These circuit elements are connected and arranged as shown in FIG. 3.

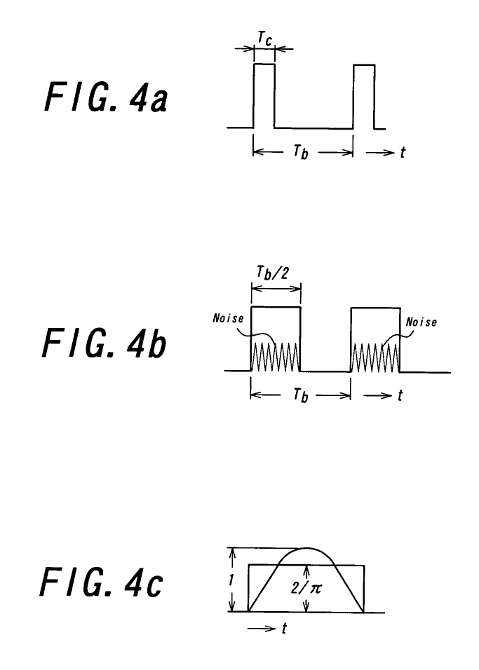

FIGS. 4a, 4b and 4c show the strength of respective signals derived when the sinusoidal wave is sampled by the SS signal that is not synchronized with the sinusoidal wave, assuming that SS signal, pulse string in the case of duty ratio D_{R} being 0.5(T_{C}=T_{B}/2) and the baseband signal, are a sinusoidal wave of analog signal, respectively.

The signal strength is shown by the area of the half period of the sinusoidal wave, and its mean value becomes 2/π.

Moreover, assuming that the baseband signal is a sinusoidal wave of analog signal, the strength of the signal obtained by sampling its sinusoidal wave with the SS signal synchronized with the sinusoidal wave signal, can be obtained as the peak value of the sinusoidal wave always obtained during the half period of the sinusoidal wave, so that its mean value is 1.

Hereinafter, the S/N improvement of a system according to the present invention, that is, a system for performing the SS modulation only at receiving side, is examined as follows.

First of all, the maximum value of pulse width T_{c} of the SS signal is T_{b}/2 (T_{b} is a pulse duration), so that the noise strength Nᵢ of the received input signal becomes a noise included in the maximum value T_{b}/2.

Therefore, noise strength Ni of the received input signal can be shown by the following expression.

Nᵢ=(n·T_{b})/2

where, n is level of noise shown in FIG. 4b.

Moreover, if n is assumed to be a level of the same noise, noise strength No of the output signal after SS modulation can be shown by the following expression.

Nₒ=nT_{c}

The following expression is obtained from these both equations.

Nₒ/Nᵢ=2·(T_{c}/T_{b})=2D_{R} (4)

Next, if signal strength of the received input signal is assumed to be Sᵢ when the sinusoidal wave is not synchronized with the SS signal, the signal strength Sₒ of the output signal after SS modulation becomes following equation.

Sₒ=(2/π)Sᵢ

Therefore,

S₀/Sᵢ=2/π≅−3.9 dB (5)

Moreover, when the sinusoidal wave has synchronized with the SS signal as well as described above, if signal strength of the received input signal is assumed to be Sᵢ

Sₒ=Sᵢ

Therefore, following equation (5′) is obtained.

Sₒ/Sᵢ=1 (5′)

From the above, S/N improvement effect ((S/N)up) according to the present invention is represented as follows, when the sinusoidal wave is not synchronized with the SS signal, by taking the ratio of the equation (5) and the equation (4),

$$\begin{matrix}( S / N ) up = ( {S}_{o} / {S}_{i} ) / ( {N}_{o} / {N}_{i} ) \\ = ( 2 / π ) \cdot / \{ 2 \cdot ( {T}_{c} / {T}_{b} ) \} \\ = 1 / \{ π \cdot ( {T}_{c} / {T}_{b} ) \} \\ = 1 / ( π \cdot {D}_{R} )\end{matrix} \qquad ( 6 )$$

Moreover, when the sinusoidal wave is synchronized with the SS signal, the following expression is obtained by taking the ratio of the equation (5′) and the equation (4),

$$\begin{matrix}( S / N ) up = ( {S}_{o} / {S}_{i} ) / ( {N}_{o} / {N}_{i} ) \\ = {T}_{b} / ( 2 {T}_{c} ) \\ = 1 / ( 2 {D}_{R} )\end{matrix} \qquad ( {6}^{′} )$$

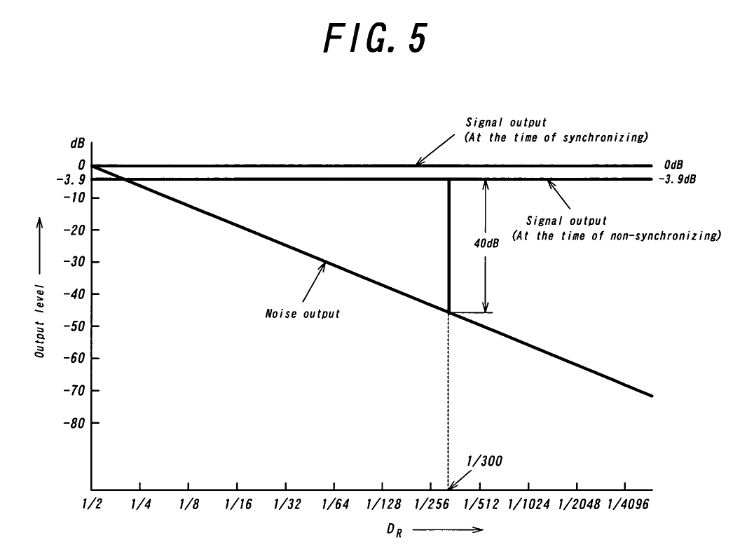

FIG. 5 shows a relation of Nₒ/Nᵢ=2D_{R} represented by the above described equation (4), a relation of Sₒ/Sᵢ=2/π≅−3.9 dB represented by the equation (5) and, a relation of Sₒ/Sᵢ=1 represented by the equation (5′) by taking the duty ratio D_{R} on abscissas, and by taking the output level on ordinate, respectively.

As understood from FIG. 5, now, if the duty ratio D_{R} is 1/300, the level of Nₒ/Nᵢ represented by the equation (4) is positioned at about 40 dB lower than the level of Sₒ/Sᵢ represented by the equation (5). That is, according to the present invention, it is shown that only the noise level is suppressed by about 40 dB.

In this way, there has a nature that when the duty ratio D_{R} of SS modulation is changed by the received input signal and the output signal after the SS modulation, though the level of Sₒ/Sᵢ is not changed, the smaller the duty ratio D_{R} is, the smaller the level of Nₒ/Nᵢ is. A numerous noise reduction of the received signal can be performed by utilizing this nature.

However, it seems common sensibly, that when duty ratio D_{R} becomes small and the pulse width narrows, the signal is also attenuated with the noise simultaneously, and SN ratio S/N is not changed, but, actually, the phenomenon that the signal is not attenuated since it is pulse-width-modulated, and only the noise decreases by the inclination of the sampling pulse, is caused. This is explained as to an actual circuit.

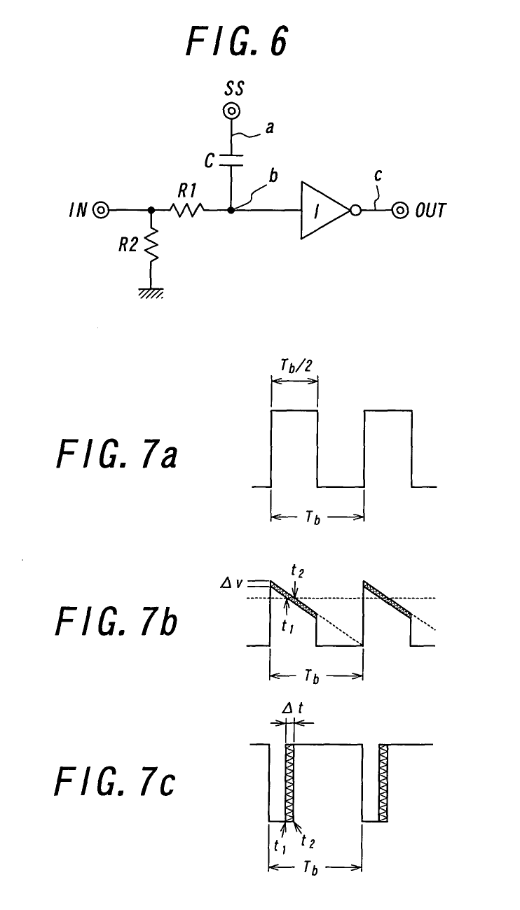

FIG. 6 is one constructional embodiment of a convenient pulse width modulation circuit constituted by using the inverter element to realize an implementation of the present invention.

Moreover, FIGS. 7a, 7b, and 7c show signal waveform diagrams representing parts shown by a, b, and c respectively, in the circuit of FIG. 6.

The pulse width modulation circuit (constituting SS modulation circuit) shown in FIG. 6 comprises respective terminals of a signal input terminal IN, an SS signal input terminal SS and a modulation output terminal OUT, and its circuit elements comprise an inverter I, a capacitor C, a resistor R1, and a resistor R2 which are connected as shown in FIG. 6.

Operation thereof is explained.

First of all, assuming that a signal voltage Δv of the input signal is inputted to signal input terminal IN. On the one hand, the SS signal with 0.5 duty ratio DR shown in FIG. 7a is applied to the SS signal input terminal SS. The capacitor C, the resistor R₁, and the resistor R₂ in the circuit constitute a differentiating circuit of time constant (C·(R₁+R₂)), so that the SS signal applied to the input terminal SS is differentiated, thereby becoming a sawtooth pulse, and is inputted to the input terminal of the inverter I (refer to FIG. 7b).

At this time, the resistor R₁ and the resistor R₂ of the differentiating circuit constitute a voltage dividing circuit, and a signal voltage Δv is applied between the junction of both resistors and the ground point. Therefore, the above sawtooth pulse applied to the input terminal of inverter I will be pulse-width-modulated according to the level of signal voltage Δv. When the level of the pulse-width-modulated sawtooth pulse exceeds the threshold level that is set to inverter I, the inverter I becomes active, so that the pulse width modulation wave shown in FIG. 7c is taken out of modulation output terminal OUT.

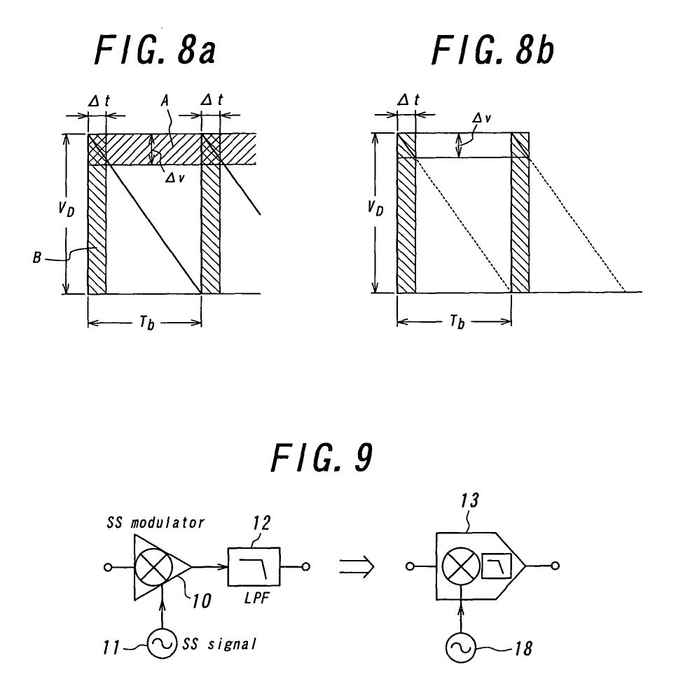

FIG. 8 shows the situation in which the SS signal is subjected to pulse width modulation.

The S/N improvement effect due to the pulse width modulation is explained by using FIG. 8.

In FIG. 8, when the level of signal voltage Δv is changed, pulse width Δt of the output pulse of inverter I and thus the duty ratio D_{R} of the SS signal is decided by the vertical line passing through the point that the changed level thereof intersects with a diagonal line of the sawtooth.

At this time, the area of the part represented by a hatching shown in FIG. 8a becomes equal to each other in an oblong rectangular part A and in a longitudinal rectangle part B, so that the relation of the following expression is obtained,

Δt·V_{D}=Δv·T_{b}

where VD is power-supply voltage of the circuit, Therefore, following equation is obtained.

Δv/V_{D}=Δt/T_{b}=D_{R} (7)

As a concrete example, assuming that power-supply voltage V_{D}=3V and signal voltage Δv=10 m V, by substituting these values for the equation (7), a following relation is obtained.

Δv/V_{D}=0.01/3=1/300=Δv/T_{b}

Therefore, when the sampling pulse of the waveform of FIG. 8b is used, both the signal and the noise have been passed through the circuit only during the period of Δt.

Whereas the signal is passed without attenuating by the fact that Δv is converted into Δt, the noise is passed through only during the period of Δt, so that Δt corresponds to T_{c} of the SS signal shown in FIG. 4a, and therefore, the duty ratio D_{R} becomes as shown in the following expression.

Δt/T_{b}=1/300

Referring to FIG. 5, the S/N improvement effect will be obtained by about 40 dB at the duty ratio D_{R}=1/300.

This is identified from the fact that a thermal noise is not generated at all as the result of applying the noise reduction method according to the present invention to the medium wave radio receiver described later.

Here, the fact that Shannon's theorem can be derived from the above equation (4) and the equation (5), is explained.

Shannon's theorem is given by the equation shown by the equation (8).

C=W·log₂((P+N)/N) (8)

where, C is communication capability [bps]

W is transmission bandwidth [Hz]

P is average signal power [W]

N is average noise electric power [W]

This theorem shows the feature that if the transmission bandwidth W is very wide, no matter how transmitting power P is small, a constant communication capability can be ensured, and is assumed to be theoretical grounds of the spread spectrum system. When the theorem is applied to the equations (4) and (5), noise output No is shown by the following expression, since the noise input is \sqrt{N}

$${N}_{o} = 2 \cdot ( {T}_{c} / {T}_{b} ) \cdot \sqrt{N}$$

Since the signal input is

$$\sqrt{( N + P )} ,$$

signal output So is shown by the following expression.

$${S}_{o} = ( 2 / π ) \sqrt{( N + P )}$$

Therefore, S/N can be shown by the following expression.

$$\begin{matrix}{S}_{o} / {N}_{o} = ( 2 \cdot \sqrt{( N + P )} / π ) \cdot ( {T}_{b} / ( 2 \cdot \sqrt{N} \cdot {T}_{c} ) \\ = ( 1 / π ) \cdot ( {T}_{b} / {T}_{c} ) \cdot \sqrt{( N + P ) / N}\end{matrix} \qquad ( 9 )$$

Now, assuming that when the value of S/N is x, the communication can ensured, following expression is obtained.

$$\begin{matrix}{S}_{o} / {N}_{o} = x \\ = ( 1 / π ) \cdot ( {T}_{b} / {T}_{c} ) \cdot \sqrt{( N + P ) / N}\end{matrix}$$

Therefore,

$$π \cdot x \cdot ( {T}_{c} / {T}_{b} ) = \sqrt{( N + P ) / N}$$

Here, the variable transformation is performed, and assuming that π·x·(T_{c}/T_{b})=2^{y(Tc/Tb)}, a following expression is obtained.

$${2}^{y ( Tc / Tb )} = \sqrt{( N + P ) / N}$$

Therefore, following equation (10) is obtained.

1/Tb=(1/(2y·T_{c}))·log₂((N+P)/N) (10)

In the equation (10), assuming that 2y=1, 1/T_{b}=C, and 1/T_{c}=W, so that when these values are substituted for the equation (10), the following expression is obtained.

C=W·log₂((P+N)/N)

This is not different from the Shannon's theorem explained by the equation (8), and the feature that equations (4) and (5) correspond to the Shannon's theorem. can be proven.

Moreover, if 1/T_{b}=C, 1/T_{c}=W are substituted for the equation (9), the following expression is obtained,

$$\begin{matrix}{S}_{o} / {N}_{o} = ( 1 / π ) \cdot ( {T}_{b} / {T}_{c} ) \cdot \sqrt{( N + P ) / N} \\ = ( 1 / π ) \cdot ( W / C ) \cdot \sqrt{( N + P ) / N}\end{matrix} \qquad ( 11 )$$

In the SS communication term, 1/D_{R}=T_{b}/T_{c}=W/C is referred to as a spread coefficient, so that from the above equation (11), the Shannon's theorem can be paraphrased as that no matter how input signal electric power P is small if the spread coefficient is made large, S/N can make largely any much. The present invention applied this matter.

As described above, according to the present invention, the noise reduction can be carried out by performing the SS modulation only at the receiving side. In addition, if the SS modulation is performed only at receiving side, the number of times of the SS modulation is not limited to one time and can be performed even times how many, and the noise reduction effect can be obtained only by the number of times.

Now, assuming that to make the notation of Figure easy, as shown in FIG. 9, the SS modulation circuit shown in FIG. 3 is represented by schematic symbol.

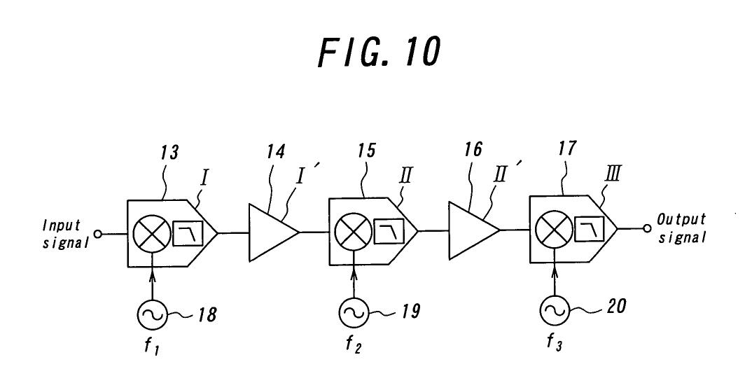

FIG. 10 shows a constructional embodiment in which the SS modulator is cascaded by as many as three steps through the amplifier, by this notification.

In the connection arrangement of FIG. 10, 13 is an SS modulating stage 1, 14 is an amplifier 1, 15 is an SS modulating stage 2, 16 is an amplifier 2, 17 is an SS modulating stage 3, 18 is an SS signal 1, 19 is an SS signal 2, and, 20 is an SS signal 3.

The operation of respective steps in this construction is as follows.

First of all, the SS modulating stage 1 shown by sign 13 reduces the external noise, the SS modulating stage 2 shown by sign 15 is reduces the thermal noise generated from the amplifier 1 (shown by sign 14), and, the SS modulating stage 3 shown by sign 17 reduces the thermal noise generated from the amplifiers 1 and 2 (shown by signs 14 and 16, respectively).

As the above, by performing the SS modulation, the reduction of the thermal noise generated from the amplifier can be performed, so that the signal can be amplified noiseless.

Moreover, in the construction shown in FIG. 10, respective different functions can be provided for the SS modulation circuit by the frequency of the SS signal supplied to respective steps.

For example, in FIG. 10, if frequency f1 of the SS signal 1 shown by sign 18 is a local frequency of the SS modulating stage 1 shown by sign 13, the SS modulating stage becomes an intermediate frequency (IF) conversion stage. Moreover, if frequency f3 of the SS signal 3 shown by sign 20 has synchronized with the input frequency of the SS modulating stage 3 shown by sign 17, the SS modulating stage becomes a synchronous detection circuit, and can provide an interference removal function.

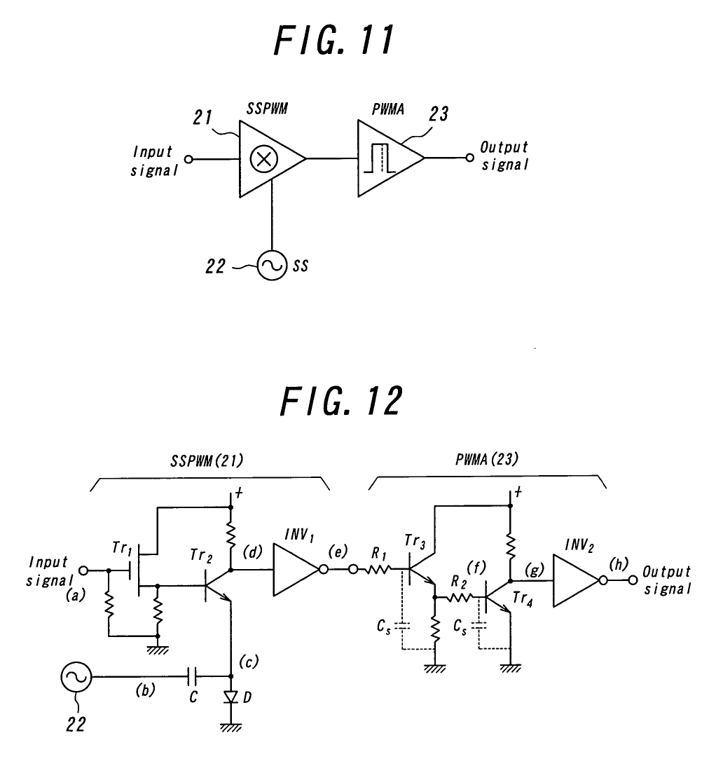

Hereinafter, the embodiment of the noise reduction pulse width modulating and amplifying circuit constituted by using the noise reduction apparatus according to the present invention is explained with reference to FIG. 11. In FIG. 11, SSPWM is a spread spectrum pulse width modulation circuit 21 having the noise reduction function according to the present invention, PWMA is a pulse width amplifier circuit 23, and SS is an SS signal source 22.

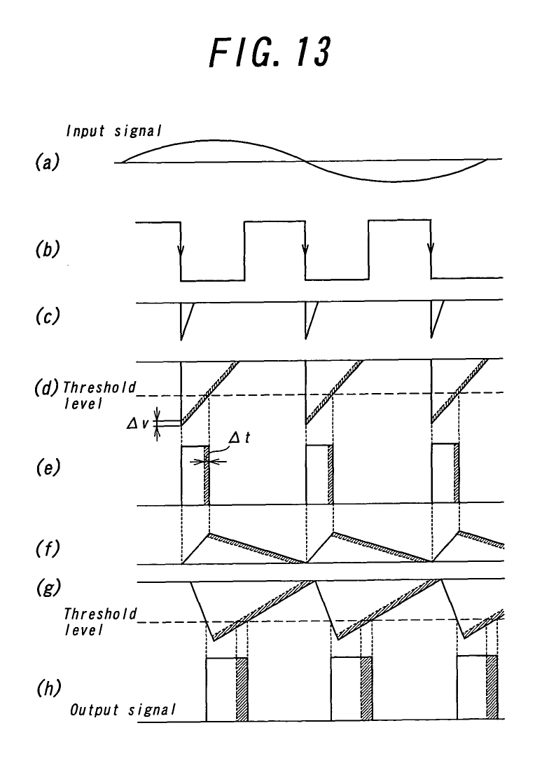

FIG. 12 shows an actual circuit configuration of such a noise reduction pulse width modulating and amplifying circuit. In FIG. 12, a field-effect transistor, a PNP transistor, an inverter circuit, a diode, a resistor, and a capacitor are connected as shown in the Figure.

The operation of the respective portions of such a circuit is explained by using the waveforms shown in FIG. 13.

First of all, in spread spectrum pulse width modulation circuit SSPWM, a transistor Tᵣ₁ is a buffer amplifier, and an input signal (a) is supplied to the base of a transistor Tᵣ₂. (b) is a sampling signal, and a steep triangular waveform (c) differentiated by a capacitance C and a diode D, is applied to the emitter of the transistor Tᵣ₂. Therefore, the waveform at the collector of the transistor Tᵣ₂ becomes a triangular wave (d) formed by the amplitude modulation of the input signal (a). In the section of Δt during which a tip of a triangular wave becomes below the threshold level, an inverter INV₁ turns on, thereby forming a pulse width modulation wave (e) which is noise-reduced.

The above is an operation of a spread spectrum pulse width modulation circuit SSPWM. Then, as an operation of the pulse width amplifier circuit PWMA, firstly, a waveform (e) is integrated by a resistor R₁ of base of a transistor Tᵣ₃ and a stray capacitance Cₛ, and a resistor R₂ of base of a transistor Tᵣ₄ and the stray capacitance Cₛ (Cₛ is a stray capacitance between the base of the transistor and the ground.), so that a waveform (f) at the base of transistor Tᵣ₄ is subjected to an amplitude modulation, thereby forming a triangular wave of a gradual inclination. The waveform at the collector of the transistor Tᵣ₄ becomes a triangular wave (g) in which the waveform (f) is amplified. Again, when the tip of the triangular wave becomes below the threshold level, an inverter INV₂ turns on, thereby forming a pulse width modulated wave (e), which becomes an output signal. The pass band of the circuit is decided by a sampling frequency fs of the SS signal, and has the following function.

1. When the sampling frequency fs is 100 KHz, the noise reduced amplifying from direct current to 30 KHz can be performed. The present noise reduction pulse width modulating and amplifying circuit has a particularly large effect for noise reductions such as the noise reduction amplification, the scratch noise, the tape noises, and line noise or the like, to sensors of slight sensitivity such as the hearing aid, the microphone, and medical equipment.

2. When the sampling frequency fs is 5 MHz, the noise reduced pulse width amplifying from direct current to 2 MHz can be performed.

3. When the sampling frequency fs is made over 15 MHz, the noise reduced pulse width amplifying from direct current to 6 MHz, that is, of video signal can be performed.

4. By driving the power amplifier of D class with the use of the circuit as an exciter, the pulse width modulation transmitter from direct current to the video signal can be obtained.

5. Moreover, the circuit can be used as a mixer. In this case, assuming that the frequency of the input signal is fr, and the sampling frequency is fs, the signals with frequencies fr, fs±fr, 2fs±fr, . . . nfs±fr can be taken out.

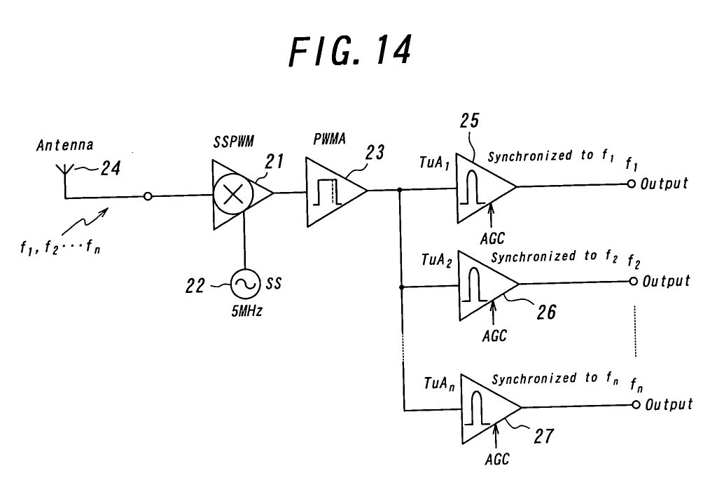

Hereinafter, the embodiment of the noise reduction pulse width modulating and amplifying circuit constituted by using the noise reduction apparatus according to the present invention is explained with reference to FIG. 11. In FIG. 14, input signals (f₁, f₂, - - - , fₙ) from a receiving antenna 24 are noise-reduced and amplified by the spread spectrum pulse width modulation circuit SSPWM21 and the pulse width amplifier circuit PWMA23. In this case, the signal of medium wave radio frequency band (531-1629 KHz) is amplified, so that the sampling frequency to spread spectrum pulse width modulation circuit SSPWM21 from the SS signal source 22 was assumed to be 5 MHz. The output of the pulse width amplifier circuit PWMA23 is amplified and outputted by tuning amplifier circuits TuAs 25, 26 and 27 tuned to frequencies (f₁, f₂, - - - , fₙ) of respective channels of the receipt input.

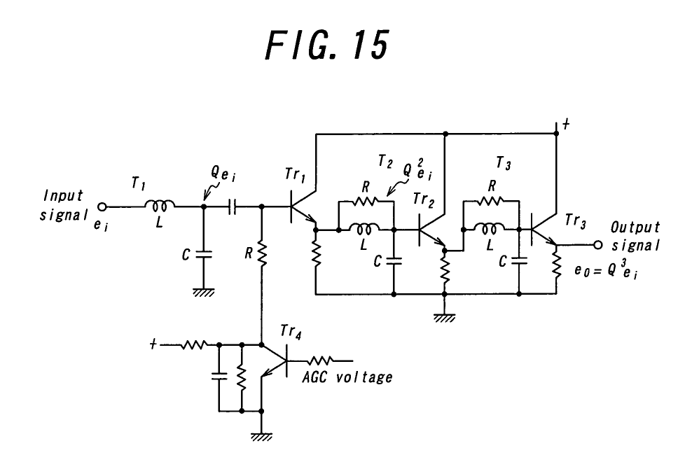

FIG. 15 shows the circuit configuration of the tuning amplifier circuits TuA (Tuning Amp). In FIG. 15, T₁, T₂, and T₃ are tuning circuits, which are constituted by an inductance L, a capacitance C, and a resistor R. In tuning frequency f₀(=½π\sqrt{LC}), assuming that an input voltage of the inductance L is eᵢ, the voltage of Qeᵢ(Q=R/2πf₀L) is obtained across the capacitance C. The feature of being amplified with the tuning circuit, and being obtained the voltage Q times, is to be risen the antenna gain Q times, so that if the value of Q is 10, the gain of the antenna is raised by 20 dB. When the output of the tuning circuit T₁ is connected to following tuning circuit T₂ through the buffer amplifier of the transistor Tᵣ₁, the output thereof becomes Q²eᵢ, and by connecting the output thereof to a tuning circuit T₃ through the transistor Tᵣ₂, the voltage of Q³eᵢ is obtained at the emitter output of the transistor Tᵣ₃. In this embodiment, assuming that Q=10, Q³=1000=60 dB, that is, as to all channels (f₁, f₂, - - - , fₙ), the antenna gain was improved by 60 dB. However, when the value of Q is adjusted to 10 or more and the gain is raised, the circuit has been oscillated, so that the gain of the tuning circuit at one frequency is 60 dB, which is its limitation.

The transistor Tᵣ₄ is for AGC control, and when the input level thereof is risen, the plus voltage is added to the base of the transistor Tᵣ₄, the voltage at the collector falls, and the voltage at the base of the transistor Tᵣ₁ falls, and thus amplification degree of transistors Tᵣ₁, Tᵣ₂, and Tᵣ₃ decrease, so that the output voltage e₀ is controlled so as to become it below a constant level.

Assuming that the receiving antenna is made as a bar antenna used for the medium wave radio receiver, the gain of the bar antenna is −57 dB (1 MHz), so that the gain of the bar antenna becomes +3 dB by the gain 60 dB of the tuning and amplifier circuit. This shows that the gain of +3 dB is as many as 30 dB higher than the loop antenna of the large scale (gain −27 dB), and thus a large-scale loop antenna of high cost can be replaced with a low-cost bar antenna.

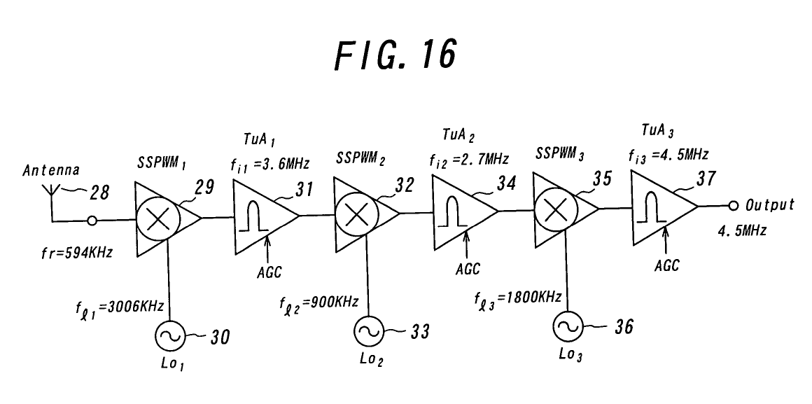

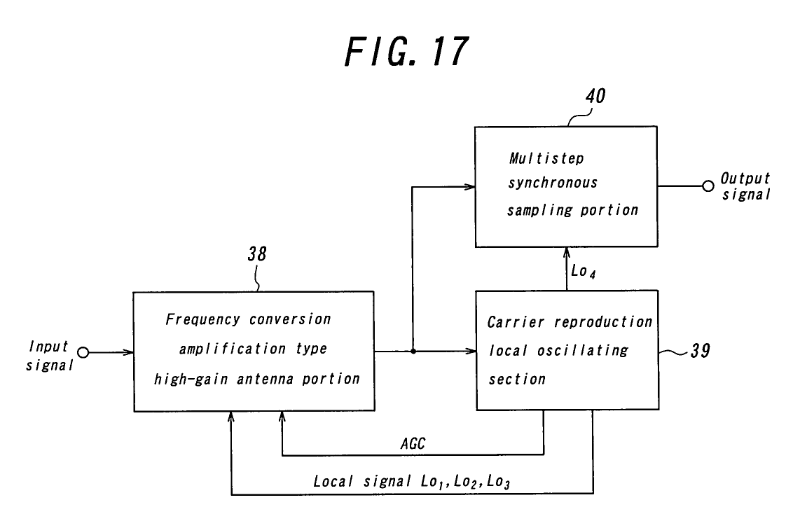

Hereinafter, the embodiment of the noise reduction high-gain antenna section of frequency conversion and amplification type, which is constituted by using the noise reduction apparatus according to the present invention, is explained with reference to FIG. 16.

As in the same way as described above, the limit of gain of tuning and amplifier circuits TuAs 3, 34, and 37, is 60 dB, respectively. To obtain amplification more than the above limit, the frequency should be converted. The present embodiment is a system, for which the antenna input signal is frequency-modulated directly by using the mixer function of the spread spectrum pulse width modulation circuit SSPWM.

Hereinafter, the explanation of respective elements of the frequency conversion amplification type noise reduction high-gain antenna section shown in FIG. 16 is enumerated.

### SSPWM₁

The antenna input is supplied by a local oscillation frequency fl₁, and the noise reduction conversion is performed by the intermediate frequency fi₁=3.6 MHz. As an embodiment of the frequency, a received frequency fr is assumed 594 KHz and fl₁=3006KHz (594+3006=3600).

### TuA₁

IF frequency fi₁=3600 KHz is tuned and amplified by 60 dB.

### SSPWM₂

The sampling is performed with fe₂=900 KHz, and frequency 3.6 MHz is converted into frequency 2.7 MHz with the noise reduction.

### TuA₂

The frequency fi₂=2.7 MHz is tuned and amplified by 60 dB.

### SSPWM₃

The sampling is performed with fe₃=1.8 MHz, and frequency 2.7 MHz is converted into frequency 4.5 MHz with the noise reduction.

### TuA₃

The frequency fi₃=4.5 MHz is tuned and amplified by 60 dB.

The overall gain of the circuit becomes 150 dB in total, since the conversion loss of spread spectrum pulse width modulation circuit SSPWM is −30 dB according to three stage-cascade connection structure, and the gain of the tuning and amplifier circuit TuA is 180 dB according to three-stage cascade connection structure. That is, the antenna of 150 dB gain was able to be achieved.

In the present embodiment, the present invention was applied to the antenna of the medium wave radio frequency, but can apply to the antenna of all the frequencies from the long wave to the SHF band by changing a local frequency. Next, FIG. 17 is a circuit diagram showing the construction of the noise, interference, and multipath disturbance reduction receiver constructed by using the noise reduction apparatus according to the present invention.

As shown in FIG. 17, the noise, interference, and multipath disturbance reduction receiver of the present embodiment, is constituted by a frequency conversion amplification type high-gain antenna portion 38, a carrier reproduction, local oscillating section 39, and a multistep synchronous sampling portion 40.

### Necessity of Carrier Reproduction

The random noise can be reduced by performing the spread spectrum pulse width modulation with the use of the arbitrary sampling frequency, but neither the jamming wave as the continuous wave nor the multipath transmission jamming components, can be reduced. The jamming wave and the multipath transmission jamming components can be reduced by sampling them with the pulse synchronized with the desired wave signal.

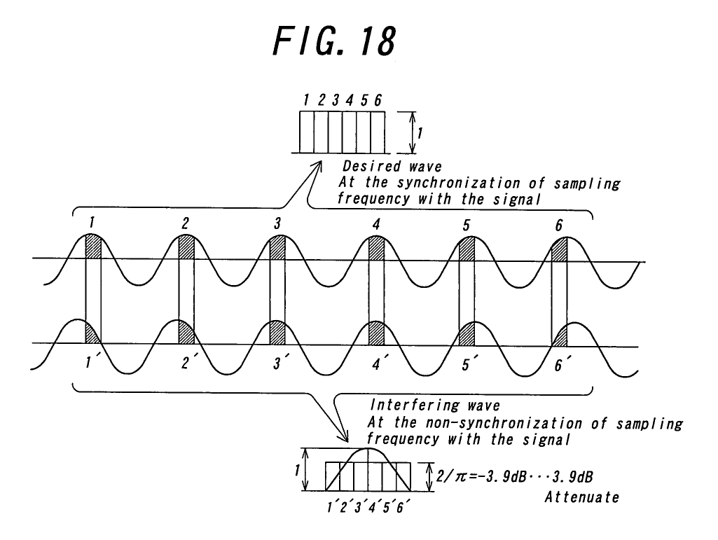

The operation thereof is explained by using the waveform shown in FIG. 18. The waveform in the upper row is a desired wave, and the state that the maximum value of the waveform is sampled, is shown, and when its sampling pulses are totaled, the output obtains 1=0 dB. The lower waveform is a waveform where synchronization is not taken as an interfering wave. At this time, if the sampling pulses are totaled, it becomes a waveform of the half wave of the sinusoidal wave. The mean value thereof is 2/π=−3.9 dB, so that the output which is not synchronized becomes −3.9 dB. That is, the reduction of the interfering wave can be realized by 3.9 dB. If the synchronous sampling is repeated four times, the reduction of the interfering wave can be realized by 3.9×4=15.6 dB.

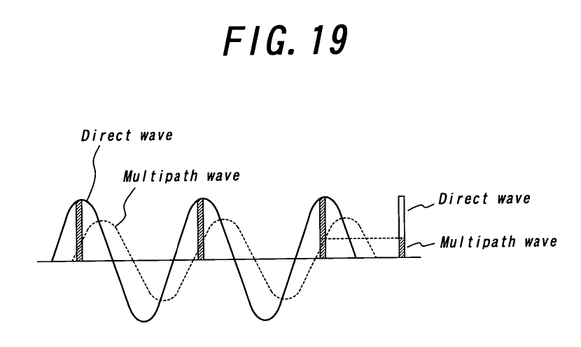

Similarly, as to the multipath disturbance, as shown in the waveform of FIG. 19, the multipath wave reaches with delay of the phase than the direct wave, so that the multipath wave is also attenuated by synchronously sampling the direct wave by a steep pulse. As shown in the embodiment of FIG. 19, in the case of the multipath wave to which the phase is delayed by 60°, the reduction can be performed by 6 dB with the synchronous sampling in one stage and by 24 dB with the synchronous sampling in 4 stages.

As described above, the sampling pulse synchronized with the input signal, is necessary to remove interference and the multipath disturbance, and thus the carrier reproduction is necessary to produce the sampling pulse.

### Carrier Reproduction and Local Oscillating Section 39

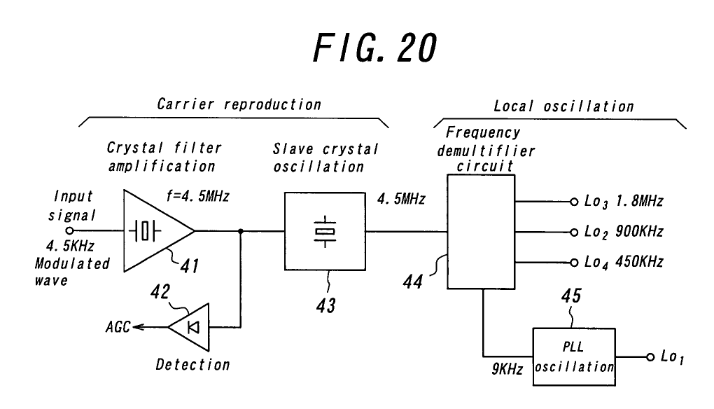

The construction of the carrier reproduction and local oscillating section 39 is shown in FIG. 20.

The carrier reproduction and local oscillating section 39 is constructed by a crystal filter amplifier circuit 41, a detector circuit 42, a slave crystal-oscillator circuit 43, a circuit 44 of dividing frequency, and PLL oscillation circuit 45, which are connected as shown in Figure. In this embodiment, the quartz vibrator was used as a filter and an oscillating element, but the ceramic oscillating element can also be used. Hereinafter, the explanation of these circuit elements is performed.

### Crystal Filter Amplifier Circuit 41

The input signal of 4.5 MHz is passed through the crystal filter, and amplified to derive a carrier component of 4.5 MHz.

### Detector Circuit 42

The carrier component of 4.5 MHz is detected to output the AGC DC voltage, thereby controlling the tuning and amplifier circuit TuA.

### Slave Crystal-Oscillator Circuit 43

The crystal-oscillator circuit is driven by 4.5 MHz carrier component to make slave oscillation and reproduce the carrier of 4.5 MHz.

### Frequency Dividing Circuit 44

The carrier-reproduced signal of 4.5 MHz is frequency-divided to derive the local signals with frequency of L₀₃1.8 MHz, L₀₂900 kHz, L₀₄450 kHz and 9 kHz.

### PLL Oscillation Circuit 45

Oscillation circuit PLL is driven by using the frequency of 9 kHz as a reference signal, to oscillate local signal L₀₁ of frequency 1.971 kHz (3600−1629)−3069 kHz (3600−531) in 9 kHz step.

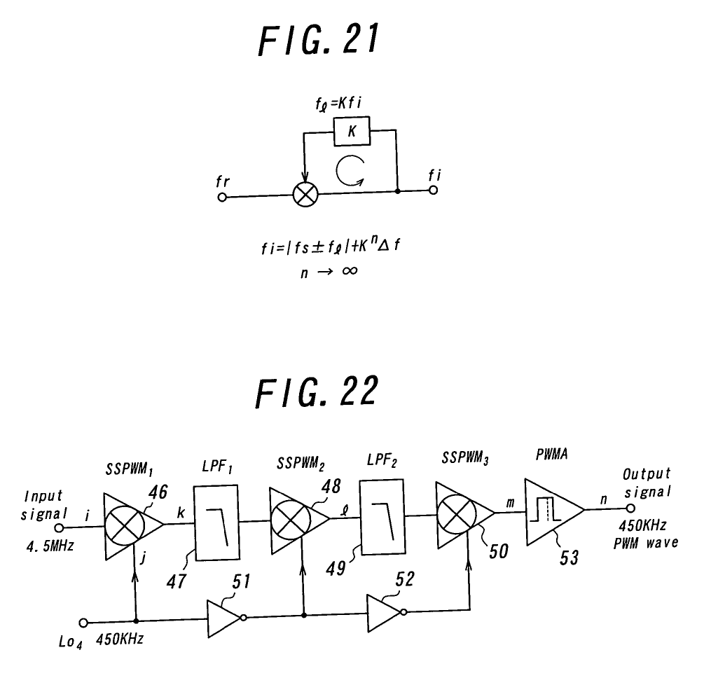

In the circuit, a system for generating the local oscillating signal from the IF signal, is adopted, and the relation among signal frequency fr, local frequency fl, and IF frequency fi is as shown in FIG. 21.

As shown in FIG. 21, assuming that fl=kfi, following relation is obtained.

fi=fr±fl+kⁿΔf.

where, Δf is an error frequency, firstly, if there is an error of Δf is present in IF frequency, the error of local frequency fl becomes kΔf, and: since it is closed-loop, so that the error becomes k²Δf, k³Δf, and kⁿΔf(n→∞).

Here, in the down-conversion system adopted for the current radio reception here, it becomes fi<fl, 1<k, therefore, kⁿΔf becomes ∞ and it is diverged.

On the contrary, in the up-conversion system adopted by the present embodiment, it becomes fl<fi, k<1, therefore, kⁿΔf→0 and it will converged. Therefore, the carrier reproduction wave of the up-conversion system of the present embodiment becomes the same precision as the received frequency fr. Permissible deflection of the radio network wave is ±10 Hz, so that the deflection of the reproduced carrier becomes ±10 Hz or less (±10 ppm in 1 MHz), too.

### Multistep Synchronous Sampling Section 40

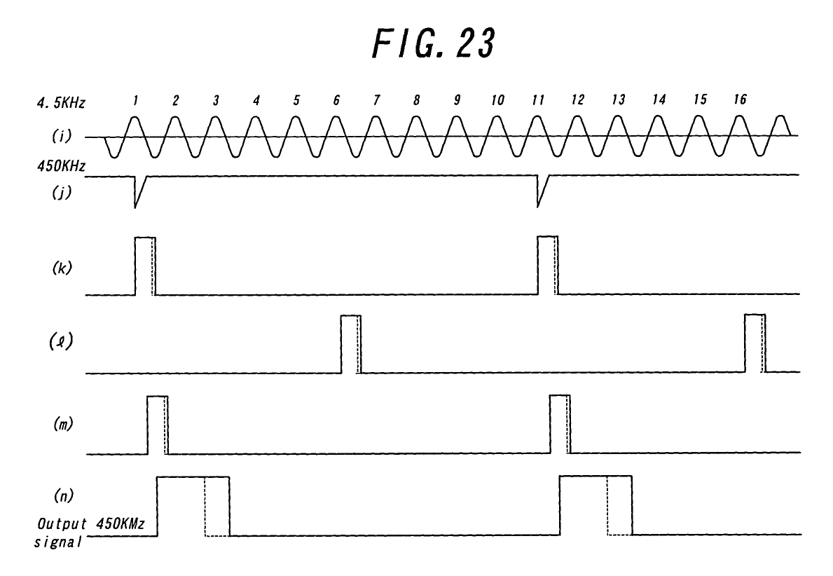

FIG. 22 shows the structure of multistep synchronous sampling portion 40. As is seen from FIG. 22, the multistep synchronous sampling portion 40 is constituted by three stages of the spread spectrum pulse width modulation circuit SSPWM and one stage of the pulse width amplifier circuit PWMA, and is a circuit performing the synchronous sampling of four times in total. The waveform of the each portion is shown in FIG. 23.

As is seen from FIG. 22, waveforms (i) and (j) sample frequency 4.5 MHz by 450 kHz, and thin out nine of ten carriers. Therefore, a large noise reduction effect is obtained. As is mentioned above, the effect of the reduction of the jamming wave and the multipath disturbance wave, of 15.6 dB was achieved by the synchronous sampling.

The above embodiment explained for the medium wave radio, but the present invention is not limited to this embodiment, but can be applied to all media.

For example, the present invention is can also be applied to the reception of the carrier suppression type and the SSB system, and thus the ionospheric propagation wave with an extreme fading of the short-wave band can be received with stability.

Moreover, when the present invention is applied to the television reception, a large effect in reductions of such as the noise, ghosts, and Sporadic E layer propagation disturbances can be obtained.

### Industrial Applicability

As described above, according to the present invention, the noise rejection from direct current to the speech signal and the video signal can be performed, and the present invention can be applied to the noise reduction of all analogues and digital transmissions. Moreover, all noises can be removed with this apparatus.

If the effect as a spread spectrum system can be achieved by only the spread spectrum process at receiving side, all systems being performed now may be changed to the spread spectrum system at receiving side. In this case, the economic effect due to the feature of omissible the spread spectrum at the transmission side, is extremely large.

The feature that sensitivity rises in the AM radio receiver applying the noise reduction apparatus according to the present invention by 20 dB or more compared with a current receiver, was identified as a result of the measurement. This shows that even if the output of the transmitter of a current radio network is decreased to 1/10, the sensitivity is still risen by 10 dB. Presently, the medium wave radio network of our country transmits about 580 waves and thus 4,750 kW with NHK together with commercial broadcastings, and the electricity cost required for the transmission thereof reaches as many as one billion yens par a year. If the transmission scale can be decreased to 1/10, by using the AM radio receiver, to which the noise reduction apparatus according to the present invention is applied, the reduction effects of the manufacturing cost of the transmitter and of the electricity cost are enormous. In addition, if seeing worldwide, the economic effect thereof is remarkably large.

Moreover, when the noise reduction apparatus according to the present invention is applied to the voice frequency band, the noise rejection filter can be obtained. From the above, the scratch noise in the record reproduction, the tape noise in the tape reproduction, and, the line noise in the telephone line can be removed, respectively.

Moreover, the carrier reproducing circuit according to the present invention can be used to the high fidelity reproduction of DSB (double sideband) and SSB (single sideband) waves.

In addition, if the noise reduction apparatus according to the present invention having the interference removal function is applied to the television reception, the jamming wave etc. according to the ghost and the sporadic E layer due to the multipath can also be removed.

1. An apparatus for reducing noises by performing the spread spectrum modulation only at receiving side, comprising means for converting a rectangular pulse string into a steep sawtooth pulse string, means for pulse-width modulating input signals with a steep sawtooth pulse string from the pulse string conversion means, and means for outputting steep pulse string which is pulse-width modulated by the pulse width modulation means, whereby the noise reduction is performed so as to improve the signal-to-noise ratio of the above output signal compared with the signal-to-noise ratio of the above input signal.

2. Noise reduction apparatus as claimed in claim 1, further comprising a pulse width extension circuit for extending the pulse width of the steep pulse string which is pulse width modulated, at following stage.

3. Noise reduction apparatus as claimed in claim 1, wherein the steep sawtooth pulse string conversion means is a differentiating circuit.

4. A carrier regenerative device for generating pulse string synchronized with input signal to be supplied to the noise reduction apparatus as claimed in claim 1 comprises means for extracting carrier components by filtering and amplifying input signal, and means for performing slave oscillation by amplifying the carrier component extracted to perform positive feedback to input side of the carrier component extracting means.

5. A carrier regenerative device as claimed in claim 4, wherein the carrier component extracting means is a first vibrator and the slave oscillation means is a second vibrator.

6. A carrier regenerative device as claimed in claim 5, wherein the vibrator is a quartz vibrator or a ceramic vibrator.
